(19) United States
(12) Patent Application Publication
(10) Pub. No.: US 2011/0194220 A1
(43) Pub. Date: Aug. 11, 2011

(54) ESD Protection Integrated at System Level

(75) Inventors: Charvaka DUVVURY, Plano, TX (US); Steve E. MARUM, Sherman, TX (US)

(73) Assignee: TEXAS INSTRUMENTS INCORPORATED, Dallas, TX (US)

(21) Appl. No.: 13/019,845

(22) Filed: Feb. 2, 2011

Related U.S. Application Data
(60) Provisional application No. 61/300,526, filed on Feb. 2, 2010.

(51) Int. Cl. H02H 9/00; H05K 13/00

(52) U.S. Cl. 361/58; 29/825

(57) ABSTRACT

An electronic system including an assembly with a protection clamp for discharging a portion of the incoming pulse, the un-discharged residual pulse (132) including a spike voltage (150, 202) for a first time duration (151, 203) followed by a bulk voltage (160, 302) smaller than the spike voltage for a second time duration (161, 303) greater than the first time duration; an integrated circuit device coupled with the board, the device allowing a peak current (211) at the insulator breakdown voltage (213), and including a pin protection clamp allowing a threshold current (311) at a threshold voltage (313) during the second time duration; and an isolation impedance integrated with the system for weakening the residual pulse, the impedance being the greater of a first resistor (220), determined by dividing the voltage difference between spike and insulator breakdown voltage through the peak current, and a second resistor (320), determined by dividing the voltage difference between the bulk and threshold voltage through the threshold current.

### FIELD OF THE INVENTION

The present invention is related in general to the field of semiconductor devices and processes, and more specifically to the concept, quantification, and implementation of system level ESD protection.

### DESCRIPTION OF RELATED ART

An electrostatic discharge (ESD) event happens when an object becomes charged (often into the thousands of volts) and then discharges to another object (in currents up to 60 A for few nanoseconds).

Integrated circuits (ICs) and whole electrical systems may be severely damaged by electrostatic discharge (ESD) events. A major source of ESD exposure to ICs is from the charged human body (described by the “Human Body Model”, HBM); the discharge of the human body generates peak currents of several amperes to the IC for about 100 ns. A second source of ESD is from metallic objects such as a charged human with a metallic tool (described by the “Machine model”, MM); it can generate transients with significantly higher rise times and current levels than the HBM ESD source. A third source is described by the “charged device model” (CDM), in which the product or the IC itself becomes charged and discharges to ground in rise times less than 500 ps.

The test methods for these models apply ESD strikes and may show that a system passes when it continues to work without interruption, or is upset by a soft error that corrects on its own, or is locked up by a soft error requiring intervention such as rebooting, or suffers a hard failure by physical damage to the system or device.

ESD phenomena in ICs are growing in importance as the demand for higher operating speed, smaller operating voltages, higher packing density and reduced cost drives a reduction of all device dimensions. This generally implies thinner dielectric layers, higher doping levels with more abrupt doping transitions, and higher electric fields—all factors that contribute to an increased sensitivity to damaging ESD events.

For many years, IC pins have been designed with a variety of ESD protections at the component level. As an example, one common scheme to protect an input/output (I/O) pad against ESD failure uses metal-oxide-semiconductor (MOS) ICs, such as nMOS transistor with its drain connected to the pin to be protected and its source tied to ground, and relies on the mode of a parasitic bipolar transistor (the source acts as the emitter, the drain as the collector, and the bulk semiconductor as the base) during an ESD event to provide a low impedance current path to ground. The protection level or failure threshold can be set by varying the nMOS device width.

The current carrying capability of the device is limited by thermal effects in the avalanching collector depletion layer. A number of effects (such as the increase of intrinsic carrier concentration, a reduction of carrier mobility, a decrease in thermal conductivity, and a lowering of the potential barrier for tunnel currents) contribute to the onset of thermal runaway, the second (thermal) breakdown. The reduction of the impact ionization current is offset by the thermal generation of carriers. Second breakdown, initiated in a device under stress as a result of self-heating, is characterized by the failure (trigger) current Iₜ₂, which is very sensitive to the device design, especially the doping profiles; it results in junction melting and in an irreversible increase in leakage currents.

Another common protection scheme used in MOS ICs employs a first diode with its cathode connected to the power (V_{DD}) terminal for positive ESD stress and its anode connected to the I/O pad to be protected. The diode has to be made of large area, since the on-resistance of the diode determines the effectiveness. A second diode has its anode connected to ground potential (Vₛₛ) for negative ESD stress and its cathode to the pad.

Electronic devices and ICs are tested for ESD according to HBM and CDM requirements to assure that they can survive manufacture in a controlled ESD environment. After the devices have been implemented in assembly boards and systems, a frequently applied test method for the robustness of the system is the IEC (International Electrotechnical Commission) ESD method, which uses the scenario of a charged human holding a metal object for discharge. The electrical industry is collecting, on an on-going basis, reports and causes of system failures. At present, the analysis of the observed system failures in case studies having both HBM and IEC data indicates no correlation of HBM failure voltage to IEC failure voltage.

### SUMMARY OF THE INVENTION

The invention is a device, system, or method for ESD protection at a system level. An isolation impedance element is placed between an internal protection clamp and an external protection clamp to protect the internal protection clamp from a residual pulse.

In one embodiment the invention is an electronic system protected against an incoming energy pulse. The electronic system comprises an assembly including a protection clamp for discharging a portion of the incoming pulse. The un-discharged residual pulse includes a spike voltage for a first time duration followed by a smaller bulk voltage for a second, longer, time duration. The electronic system further comprises an integrated circuit device tied to the assembly, the device allowing a peak current at the insulator breakdown voltage, and including a pin protection clamp allowing a threshold current at a threshold voltage during the second time duration. The electronic system also includes an isolation impedance, integrated with the assembly and device, for weakening the residual pulse. The impedance is the greater of a first resistor, determined by dividing the voltage difference between spike and insulator breakdown voltage through the peak current, and a second resistor, determined by dividing the voltage difference between the bulk and threshold voltage through the threshold current.

In another embodiment, the invention is a method for fabricating an electronic system protected against an incoming energy pulse. The method includes providing an assembly including an external protection clamp for discharging a first portion of the incoming pulse, leaving un-discharged a residual pulse having a voltage/time characteristic and analyzing the voltage/time characteristic for identifying a first regime having a spike voltage for a first time duration followed by a second regime having a bulk voltage smaller than the spike voltage for a second time duration greater than the first duration. The method further includes coupling an integrated circuit device to the assembly, the device allowing a peak current at the insulator breakdown voltage, and further including a pin with an internal protection clamp having a current/voltage failure characteristic for the second time duration allowing a threshold current at a threshold voltage. The method also includes integrating into the system of assembly and device the greater isolation impedance between a first resistor being equal to or greater than the voltage difference between spike and oxide breakdown voltage divided by the peak current and a second resistor being equal to or greater than the voltage difference between the bulk and threshold voltage divided by the threshold current.

In another embodiment the invention is an integrated circuit device having an I/O pin, an internal protection clamp; and an isolation impedance element connected between the internal protection clamp and the pin. The isolation impedance element has a resistance in the range of 5Ω to 100Ω. For example, the isolation impedance element may be selected such that the resistance between the internal protection clamp and a theoretical external protection clamp is not less than a voltage difference between an expected spike voltage and an oxide breakdown voltage of the internal protection clamp divided by an allowed peak current and not less than a voltage difference between an expected bulk voltage and a threshold voltage of the internal protection clamp divided by an allowed threshold current.

### BRIEF DESCRIPTION OF THE DRAWINGS

FIG. 1 illustrates the residual pulse concept for an electronic system with an external clamp (transient voltage suppressor) on the board and an internal clamp in the device tied to the board.

FIG. 2 depicts the function and calculation of a first isolation impedance to survive a first phase of the residual pulse.

FIG. 3 illustrates the function and calculation of a second isolation impedance to survive a second phase of the residual pulse.

FIG. 4 shows an embodiment of the methodology, an implementation of the isolation impedance in a trace of the assembly board.

FIG. 5 shows another embodiment of the methodology, an implementation of the isolation impedance in the package of the semiconductor device.

FIG. 6 shows another embodiment of the methodology, an implementation of the isolation impedance in the integrated circuit chip of the semiconductor device.

### DETAILED DESCRIPTION OF THE PREFERRED EMBODIMENTS

ESD protections for semiconductor device pins are typically designed for protecting against the stress of an electrostatic pulse at the component level. Applicants observed that for devices inserted in systems, these component-level protections are most often not compatible with a system level pulse, which is often more energetic than a component level pulse. Today, system-level protection against stress is generally not harmonized with component-level protection. Further, the discharge paths and the associated currents in the HBM/CDM and IEC case studies are different for these stress methods, as the lack of correlation of the failure data indicates. An improved device defense by arbitrarily increasing the component level protection typically reduces device speed and is thus not recommended. Simply accepting a higher risk of device and thus system failure is generally not an option, either.

Applicants solved the problem of the discrepant board and device protection methodologies by introducing a system integrated approach with the concept of a residual pulse. After a portion of the arriving pulse energy has been discharged to ground by the board level external protection clamp, questions are asked whether the component level internal clamp of the device pin can survive the residual pulse energy. Applicants discovered that the residual pulse energy can be neutralized by additional so-called isolation impedances (RX) determined by the integration methodology.

For an analysis of the residual pulse stress, applicants investigated the residual pulse voltage characteristic as a function of time (stress) and found that the stress includes a first portion having a peak voltage (depending on the clamp, about 80 V) for a first, brief time duration (about 1 ns), followed by a second portion having a bulk voltage (again, depending on the clamp, about 30 to 40 V) smaller than the peak voltage for a second, longer time duration (about 100 ns). In order to survive the residual pulse, the device needs to be protected by the appropriate value of an isolation impedance RX suitable against pulse energies from both time domains. As an example, RX may be the greater of two isolation impedances (RX1 and RX2) determined by analyzing the first and the second time domains of the residual pulse. As examples, this greater impedance may be integrated in the board, in the device package, or in the circuitry of the chip.

In an embodiment, the charged device model (CDM) is used: The failure current is plotted as a function of the pulse voltage. At the oxide breakdown voltage of the device, the model allows a peak pulse current. Consequently, in order to survive the first stress portion, an isolation impedance (first isolation resistor RX1) must be greater than the voltage difference between peak and oxide breakdown voltage, divided by the peak current. At the failure threshold voltage of the second time duration, the model allows a respective failure threshold current. Consequently, in order to survive the second stress portion, an isolation impedance (second isolation resistor RX2) must be greater than the voltage difference between bulk and failure threshold voltage, divided by the failure threshold current. The greater of the isolation resistors RX1 and RX2 is then selected to be implemented in the system as the isolation impedance RX.

Other embodiments include methods for implementing the isolation resistors RX. As an example for adding RX to a system, a sufficiently large RX can be integrated into an assembly board design by implementing RX into a board trace connecting to a package pin. As another example, RX can be integrated into the package of the semiconductor device by being implanted as a component into a connection from a package pin to a chip input/output (IO) terminal. As yet another example, RX can be designed into the pin protection clamp of the component device. As an example of the latter embodiment, RX is integrated into the line between an IO terminal and the internal ESD clamp as a part of the internal clamp design.

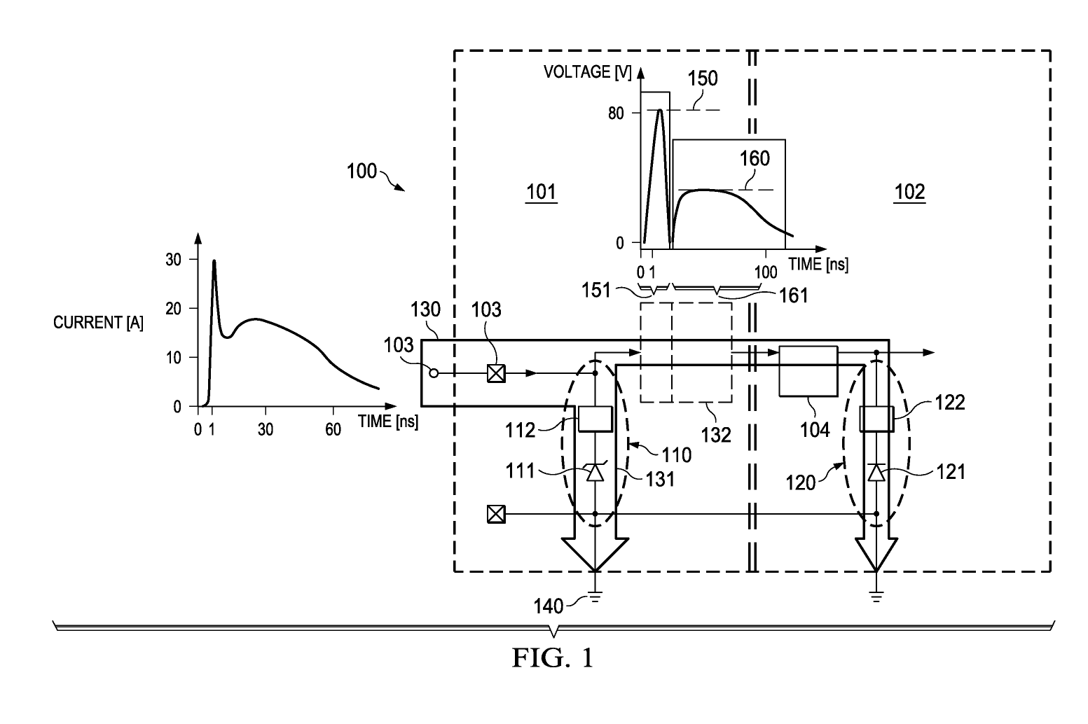

FIG. 1 presents an overview of the integrated ESD protection approach of an electronic system based on the concept of a residual pulse. The system, generally designated 100, includes a printed circuit board 101 with an external protection clamp-to-ground 110 and a semiconductor circuit device 102 with an internal clamp-to-ground 120. Internal clamp 120 is the component level ESD protection.

As depicted in FIG. 1, when a pulse 130 with energy E₁, as defined by IEC (International Electrotechnical Commission) specification 61000-4-2, arrives at the entry port 103 to stress the system, it may have a peak current of 30 A at a peak voltage of 8 kV. The peak current of 30 A may last for 1 ns and the bulk current of about 15 A average may last for 60 ns. The area under the current/time characteristic indicates the amount of electrical charge of pulse 130; the amount of charge multiplied by the voltage delivers the impinging energy E₁. A significant portion E₂ (131) of pulse E₁ (130) is discharged to electrical ground 140 by external clamp 110 (transient voltage suppressor, TVS), characterized by Zener diode 111, with a breakdown voltage VB₁, and clamp resistance r₁ (112). The impinging energy E₁ is thus reduced by the amount of energy E₂.

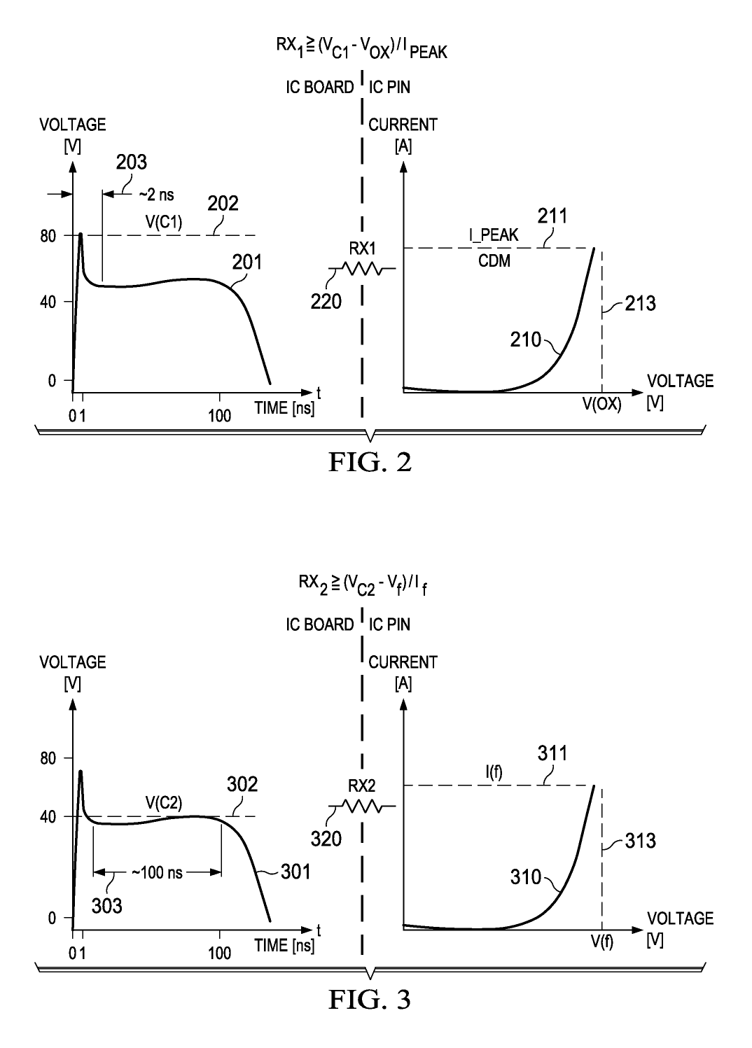

The remainder of pulse 130, referred to as residual pulse 132, arrives like a transmission line pulse (TLP) at an input/output (IO) pin 104 of device 102. The residual pulse 132 has an energy E₃=E₁−E₂ and a residual pulse current (RPC) as a function of time. FIG. 1 indicates the voltage/time characteristic of the residual pulse 132 separated in a spike voltage 150 for a time duration 151 and a lower bulk voltage 160 for a longer time duration 161. The question then arises: Since the residual pulse transfers the energy E₃ to the IO pin, is the internal clamp 120 of device pin 104 designed to survive the residual pulse? Clamp 120 is characterized by diode 121, with a breakdown voltage VB₂<VB₁, and clamp resistance r₂>r₁ (122). In order to find the answer to the survival question, the residual pulse is investigated for its stress characteristic as displayed by its voltage-versus-time plot; see FIGS. 2 and 3. The goal of the analysis is to reduce the RPC to a level, which can be sustained by the breakdown characteristics of the IO pin; on the other hand, an unnecessary strong reduction would reduce the speed (frequency) of the device, and thus needs to be avoided. Preferably, the incoming pulse should be matched by the handling capability of the device so that pulse and capability compensate each other.

The voltage/time characteristic of the residual pulse is analyzed in FIGS. 2 and 3. As illustrated, curve 201 of the residual pulse exhibits a distinctive first and second regime. As indicated in FIG. 2, after the residual pulse hits the IO pin (time 0), the voltage reaches in the first regime a spike value 202 (voltage V_{C1}) for a brief first time duration 203 (approximately 1 ns). FIG. 3 shows that curve 201 continues in a second regime with a bulk voltage 302 (voltage V_{C2}) smaller than spike voltage V_{C1} for a second time duration 303 greater than the first time duration 203. As an example, the spike voltage 202 may reach approximately V_{C1}=80 V, and the first time duration 203 may be on the order of 1 or 2 ns. The bulk voltage 302 may be approximately V_{C2}=40 V, and the second time duration 303 may be on the order of 100 ns.

In order to survive the first regime of the voltage/time relation of the residual pulse, the prime concern has to be focused on the spike voltage V_{C1} and its duration for their effect on the insulating quality of the IC oxide layers used in the IC chip circuitry. The spike voltage has to be weakened before any damage is inflicted to the insulating layers. As indicated by curve 210 in FIG. 2, CDM data establishes a correlation for a maximum current Iₚₑₐₖ (211) tolerated at the insulator breakdown voltage Vₒₓ (213), before the device IO pin fails at higher currents. Iₚₑₐₖ is dependent on the package of the semiconductor device. Consequently, an effective first isolation impedance RX₁ (220) has to satisfy the following relation:

RX₁≧(V_{C1}−V_{OX})/Iₚₑₐₖ.

As an example, for V_{C1}=80 V, V_{OX}=5 V, and Iₚₑₐₖ=2 A, the value for RX₁ has to be greater than, or at least equal to 37.5Ω for survival by the IO pin of the first regime of the residual pulse.

Referring now to FIG. 3, in order to survive the second regime of the voltage/time relation of the residual pulse, the current/voltage failure characteristic of the internal protection clamp of the device IO pin has to be considered for the second time duration 303. It should be pointed out that the current/voltage characteristic of FIG. 3 is different from the current/voltage characteristic of FIG. 2 in spite of some superficial similarity of the curves, since in FIG. 2, the relationship is obtained using CDM pulses, while in FIG. 3 the relationship is obtained with 100 ns TLP pulses (or something similar). As FIG. 3 shows, the second time duration 303 marks the time duration of the bulk voltage V_{C2} (302) in the voltage/time diagram. As indicated by curve 310 in FIG. 3 of the current/voltage pulse diagram, at the failure threshold voltage V_{f} for the second time duration, the model allows a respective failure threshold current I_{f}, before the device IO pin fails at higher currents. Consequently, an effective second isolation impedance RX₂ (320) has to satisfy the following relation:

RX₂≧(V_{C2}−V_{f})/I_{f}.

As an example, for V_{C2}=40 V, V_{f}=7 V, and I_{f}=1 A, the value for RX₂ has to be greater than, or at least equal to 33Ω for survival by the IO pin of the second regime of the residual pulse.

In order to ensure that the IC IO pin of the semiconductor device can survive the complete residual pulse, the greater isolation impedance between RX₁ and RX₂ has to be integrated into the system. The isolation impedance is designated RX, also referred to as the blocking resistance. In the above examples, RX₁ is the greater impedance; consequently, the isolation impedance RX to be integrated into the system has to be larger than, or at least equal to 37.5Ω). Among the embodiment options for the most convenient system locations for implementing the isolation impedance RX are the assembly board (or another external system portion), the device package, and the IC of the device chip.

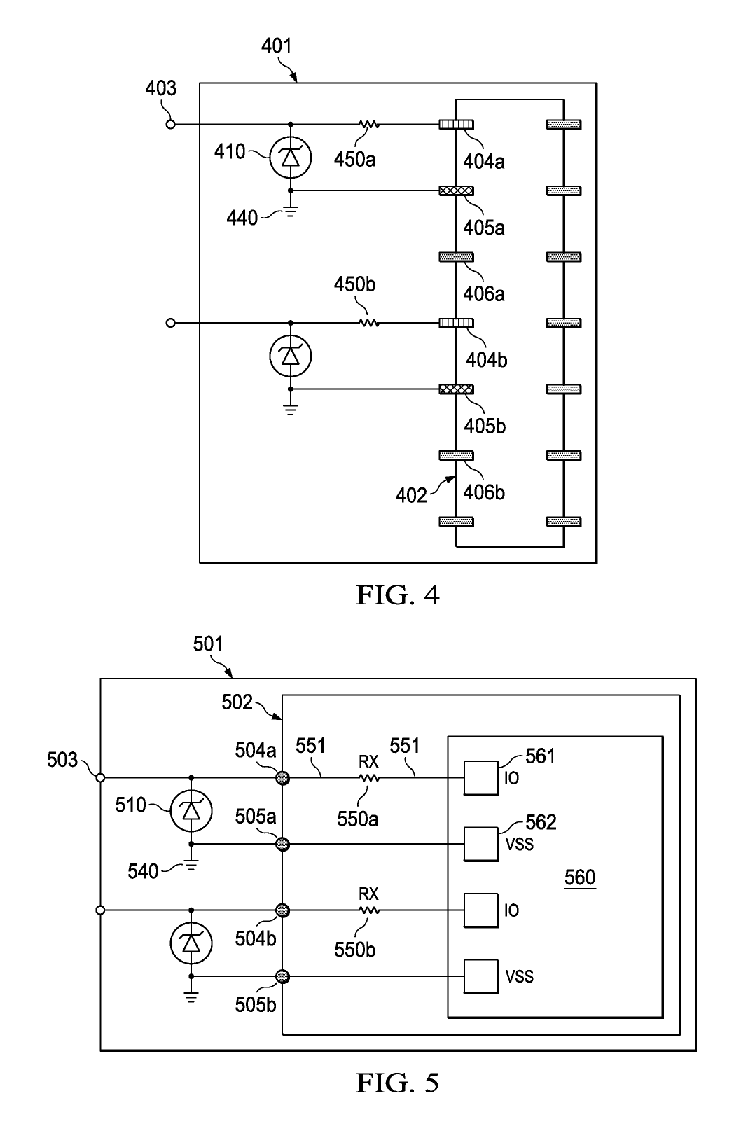

FIGS. 4, 5 and 6 show examples for several embodiments of integrating the isolation impedance, or blocking resistance, RX in the electrical system to have the pins protected against an electrostatic pulse stress. The exemplary embodiment of FIG. 4 depicts the board 401 as the location for implementing RX. Board 401 has a plurality of entry ports 403, each port with a clamp 410 to electrical ground 440. The system's IC device is designated 402; the device has a plurality of IO pins 404a, 404b, etc., ground pins 405a, 405b, etc. connected to ground, and other pins 406a, 406b, etc. In FIG. 4, the isolation impedances 450a, 450b, etc. are shown to be implemented as piece parts (e.g., a discrete resistor) in connecting traces from respective entry ports to IO pins; the piece parts have to be able to carry the discharge current. Alternatively, they may be incorporated in the traces as a genuine feature.

The exemplary embodiment of FIG. 5 illustrates the package and assembly structure 502 of the semiconductor device as the location for implementing RX. The device is incorporated in board 501, which has an entry port 503 with its clamp 510 to electrical ground 540. Package and assembly structure 502 includes the encapsulation as well as inside interconnections by wires, metal bumps, conductive adhesive, etc. for IC chip 560. The encapsulation includes outside metal contacts (pins, leads, solder balls, etc.) for external connections. Contacts connected to chip IO terminals (561) are designated 504a, 504b, etc., respectively; contacts connected to chip ground terminals (562) are designated 505a, 505b, etc., respectively. The connections 551 themselves may be bonding wires or metal bumps. In FIG. 5, the isolation impedances 550a, 550b, etc. are shown to be incorporated as separate entities in the connections (wire bonds, metal bumps); the isolation resistances have to be able to carry the discharge current. Alternatively, they may be integral with the connections as special features of the connections.

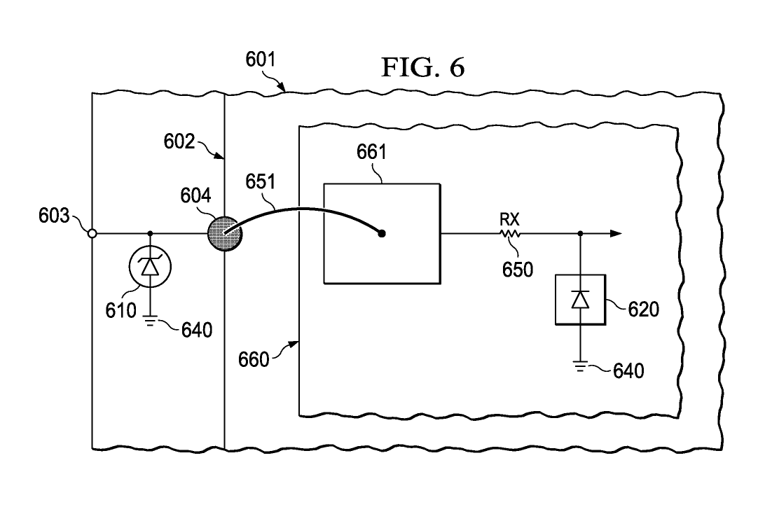

The exemplary embodiment of FIG. 6 shows the IC pin clamp as the location for implementing RX. 601 denotes the board and 603 an entry port of the board with its clamp 610 to ground 640. 602 designates the device package with a contact 604 connected (for instance by bonding wire 651) to an IO bond pad 661 of IC chip 660. The ESD clamp to ground 640 of IO pad 661 is designated 620. The isolation impedance RX (650) is an integral part of the integrated circuitry, for instance a wide enough metal layer resistance able to carry the discharge current.

In each case the isolation impedance RX provides an additional resistor to the connection between the external clamp (410, 510, 610) and the internal clamp (620) to increase the resistance beyond that necessary to complete the connection and route all other connections in the circuit. In other words, the isolation impedance RX adds resistance in addition to that found in the normal routing of the circuit, where the total resistance is determined as discussed previously. Isolation impedance RX may, for example, take the form of a discrete resistor (e.g., a carbon resistor used external to the chip or a diffused resistor or poly resistor internal to the chip), an increased length portion of the trace between the external clamp and the internal clamp, a reduced width portion of the trace between the external clamp and the internal clamp, a resistor material placed in a portion of the trace, where the resistor material has an increased resistance relative to the trace metal, or any combination of the above.

When the embodiment of the invention is an integrated circuit device (like 502 or 602) having the isolation impedance RX connected between an internal clamp (620) and the pin (504a, 504b, 604), the value of the isolation impedance RX may be selected as described above based on a theoretical external clamp along with an expected residual pulse having an expected peak voltage, allowed peak current, expected bulk voltage, and allowed threshold voltage. In this situation, the isolation impedance RX may have a resistance in the range of 5Ω-100Ω or more preferably 10Ω-50Ω, depending on the expected residual pulse.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the integrated method applies to any type of external clamp including Zener diodes, RC networks, polymer materials, and related transient voltage suppressors. As another example, the blocking impedance may be a series of impedances in a row, or a set of distributed impedances, as long as the sum value adds up to the value of the desired isolation impedance.

As another example, the blocking impedance may be an inductor or a series combination of an inductor and a resistor.

As yet another example, the concept of the invention can be applied to a methodology wherein the residual pulse current is considered as a function of time, which needs to be reduced to a level which can withstand the breakdown characteristic of the IC pin.

As yet another exemplary embodiment of the invention, a small capacitor to ground may be implemented in front of the resistor to discharge the spike voltage for its duration; in this example, solely RX₂ is defining the isolation impedance.

It is therefore intended that the appended claims encompass any such modifications or embodiments.

We claim:

1. An electronic system protected against an incoming energy pulse, comprising:
an assembly including a protection clamp for discharging a portion of the incoming pulse, the un-discharged residual pulse including a spike voltage for a first time duration followed by a bulk voltage smaller than the spike voltage for a second time duration greater than the first time duration;
an integrated circuit device tied to the assembly, the device allowing a peak current at the insulator breakdown voltage, and including a pin protection clamp allowing a threshold current at a threshold voltage during the second time duration; and
an isolation impedance, integrated with the assembly and device, for weakening the residual pulse, the impedance being the greater of a first resistor, determined by dividing the voltage difference between spike and insulator breakdown voltage through the peak current, and a second resistor, determined by dividing the voltage difference between the bulk and threshold voltage through the threshold current.

2. The system of claim 1 wherein the isolation impedance is integrated in an assembly trace connecting to the device pin.

3. The system of claim 1 wherein the isolation impedance is integrated inside the device package in a connection from a package terminal to a chip terminal.

4. The system of claim 1 wherein the isolation impedance is integrated on the circuitry of the device chip in a conductive line from a chip terminal to the internal protection clamp.

5. A method for fabricating an electronic system protected against an incoming energy pulse, comprising the steps of:
providing an assembly including an external protection clamp for discharging a first portion of the incoming pulse, leaving un-discharged a residual pulse having a voltage/time characteristic;
analyzing the voltage/time characteristic for identifying a first regime having a spike voltage for a first time duration followed by a second regime having a bulk voltage smaller than the spike voltage for a second time duration greater than the first duration;
coupling an integrated circuit device to the assembly, the device allowing a peak current at the insulator breakdown voltage, and further including a pin with an internal protection clamp having a current/voltage failure characteristic for the second time duration allowing a threshold current at a threshold voltage; and
integrating into the system of assembly and device the greater isolation impedance between
a first resistor being equal to or greater than the voltage difference between spike and oxide breakdown voltage divided by the peak current; and
a second resistor being equal to or greater than the voltage difference between the bulk and threshold voltage divided by the threshold current.

6. The method of claim 5 wherein the greater isolation impedance is integrated in an assembly trace connecting to the device pin.

7. The method of claim 5 wherein the greater isolation impedance is integrated inside the device package in a connection from a package terminal to a chip terminal.

8. The method of claim 5 wherein the greater isolation impedance is integrated in the circuitry of the device chip in a conductive line from a chip terminal to the internal protection clamp.

9. An integrated circuit device, comprising:
an I/O pin;
an internal protection clamp; and
an isolation impedance element connected between the internal protection clamp and the pin, wherein the isolation impedance element has a resistance in the range of 5Ω to 100Ω.

10. The device of claim 9, wherein the isolation impedance element is selected to protect the internal protection clamp from an expected residual pulse from a theoretical external protection clamp such that the resistance between the internal protection clamp and the theoretical external protection clamp is:
not less than a voltage difference between an expected spike voltage and an oxide breakdown voltage of the internal protection clamp divided by an allowed peak current; and
not less than a voltage difference between an expected bulk voltage and a threshold voltage of the internal protection clamp divided by an allowed threshold current.

11. The device of claim 9, wherein the isolation impedance element is a discrete resistor part.

12. The device of claim 9, wherein the isolation impedance element comprises a resistor material having a higher resistance than a resistance of a metal connected between the internal clamp and the pin.

13. The device of claim 9, wherein the isolation impedance element comprises a portion of a metal connected between the internal protection clamp and pin having an additional length.

14. The device of claim 9, wherein the isolation impedance element comprises a narrowed portion of a metal connected between the internal protection clamp and a pin.

15. The device of claim 9, wherein the resistance is between 10Ω and 50Ω.
